(19) United States
(12) Patent Application Publication
(10) Pub. No.: US 2026/0075892 A1
(43) Pub. Date: Mar. 12, 2026

(54) Isolation Structure and Methods of Forming Same

(71) Applicant: Taiwan Semiconductor Manufacturing Company, Ltd., Hsin-Chu (TW)

(72) Inventors: Hong-Chih CHEN, Changhua County (TW); Jin-Aun NG, Hsinchu City (TW); Ming-Heng TSAI, Taipei (TW); Shih-Hsun CHANG, Hsinchu (TW)

(21) Appl. No.: 18/883,471

(22) Filed: Sep. 12, 2024

(51) Int. Cl. H01L 29/06; H01L 21/762; H01L 21/8234; H01L 27/088; H01L 29/423; H01L 29/66; H01L 29/775; H01L 29/786

(52) U.S. Cl. CPC H10D 62/116; H10D 30/6757; H10D 64/021; H10D 84/0151; H10D 84/038; H10D 84/83; H10W 10/014; H10W 10/17; H10D 30/014; H10D 30/43; H10D 30/6735; H10D 62/121

(57) ABSTRACT

A method includes forming a stack of channel layers and sacrificial layers over a fin base, forming an isolation feature adjacent to the fin base and the stack, forming a dummy gate structure over the stack and the isolation feature, and forming a source/drain trench in the fin base and exposing sidewalls of the sacrificial layers. The sacrificial layers include a top portion and a bottom portion. The method further includes removing the top portion to form a top opening and the bottom portion to form a bottom opening, depositing a dummy layer in the top and bottom openings, selectively and partially recessing the dummy layer to form inner spacer recesses, forming inner spacer features, forming a source/drain feature, and replacing the dummy gate structure and the dummy layer in the top opening but not the dummy layer in the bottom opening with a metal gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

However, despite having many desirable features, multi-gate device fabrication has continued to face challenges as a result of the ongoing scaling down of semiconductor IC dimensions. Thus, existing techniques have not proved entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1 and 2 illustrate a flowchart of a method for forming a semiconductor structure, according to one or more aspects of the present disclosure.

FIGS. 3, 4A, 4B, 5, 6, 7, 8, 9, 10, 11, 12, 13, 14, 15, 16, 17, 18A, 18B, 19, 20A, 20B, 21A, 21B, 21C, and 21D illustrate fragmentary cross-sectional views of an exemplary semiconductor structure during various fabrication stages in the method of FIG. 1 and FIG. 2, according to one or more aspects of the present disclosure.

FIGS. 22A, 22B, 22C, and 22D illustrate fragmentary cross-sectional views of an alternative semiconductor structure during various fabrication stages in the method of FIG. 1 and FIG. 2, according to one or more aspects of the present disclosure.

FIGS. 23, 24, 25, 26, and 27 illustrate fragmentary cross-sectional views of an alternative semiconductor structure during various fabrication stages in the method of FIG. 1 and FIG. 2, according to one or more aspects of the present disclosure.

FIG. 28 illustrates a fragmentary cross-sectional view of an alternative semiconductor structure during various fabrication stages in the method of FIG. 1 and FIG. 2, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

As described above, MBC transistors may also be referred to as SGTs, GAA transistors, nanosheet transistors, or nanowire transistors. They can be either n-type or p-type. MBC devices may have channel regions disposed in nanowire channel members, bar-shaped channel members, nanosheet channel members, nanostructure channel members, bridge-shaped channel members, and/or other suitable channel configurations. An MBC transistor may generally include a stack of channel layer in a multi-layer structure disposed over a semiconductor substrate, epitaxial source/drain features formed over or in an active region (e.g., a fin), and a metal gate structure interleaved with a stack of channel layers and interposed between the source/drain features. In some examples, current leakages may occur between epitaxial source/drain features and/or between the epitaxial source/drain features and the semiconductor substrate, which may also be doped to form wells therein. Furthermore, a bottommost channel layer in the multi-layer structure may produce leakage current and potentially degrade performance of the device. While existing techniques are generally adequate for their intended purposes, they are not satisfactory in all aspects.

The present disclosure provides methods for forming a semiconductor device such as a GAA transistor. In an example process, a fin-shaped structure including a base fin structure and a stack of channel layers and sacrificial layers is formed over a substrate. An isolation feature is formed on a side of the base fin structure and a bottom portion of the stack. A top surface of the isolation feature is above a top surface of a bottommost sacrificial layer. After formation of a dummy gate stack over a channel region of the fin-shaped structure, a gate spacer is formed over the dummy gate stack. Source/drain regions of the fin-shaped structure are recessed. The sacrificial layers are selectively removed to release the channel layers as channel members. A dummy layer is deposited over each of the channel members. The dummy layer is then selectively and partially recessed to form inner spacer recesses between the plurality of channel members. Inner spacer features are formed in the inner spacer recesses. An isolation layer and an epitaxial source/drain feature are formed in source/drain recesses. The isolation layer may include a dielectric material and/or an undoped epitaxial material. After selective removal of the dummy gate stack, a top portion of the dummy layer is selectively removed to release a top portion of the channel members. A gate structure is then formed to wrap around each of the top portion of the channel members. A remaining portion of the dummy layer and the inner spacer features on its sides collectively form an isolation structure. By having the isolation structure and the isolation layer, current leakage from the channel layers and the epitaxial source/drain feature may be mitigated, latch-up issues between adjacent epitaxial source/drain features may be prevented, and trigger voltage fail may be avoided, thus overall performance of the semiconductor device may be improved.

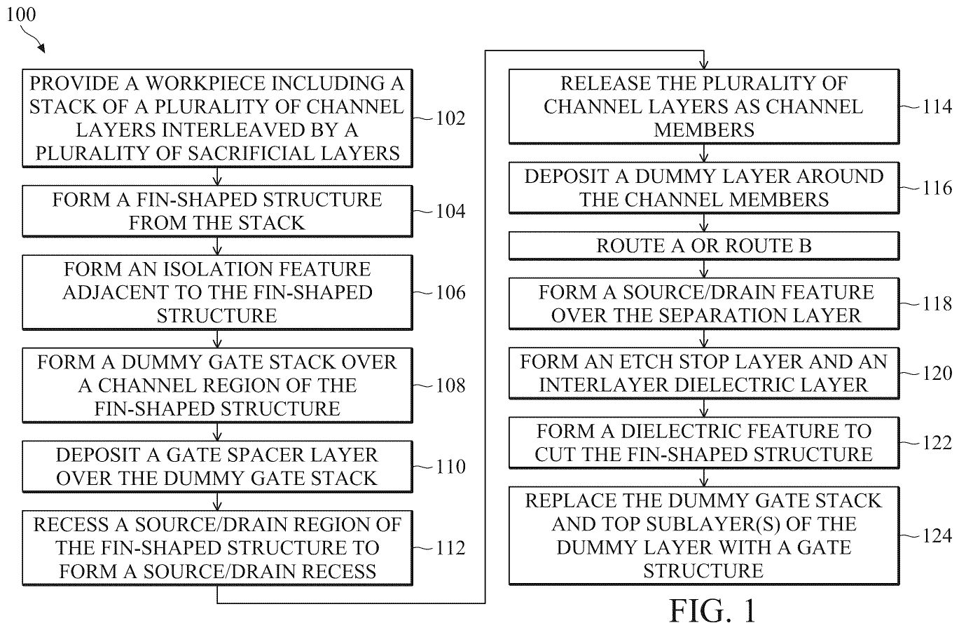

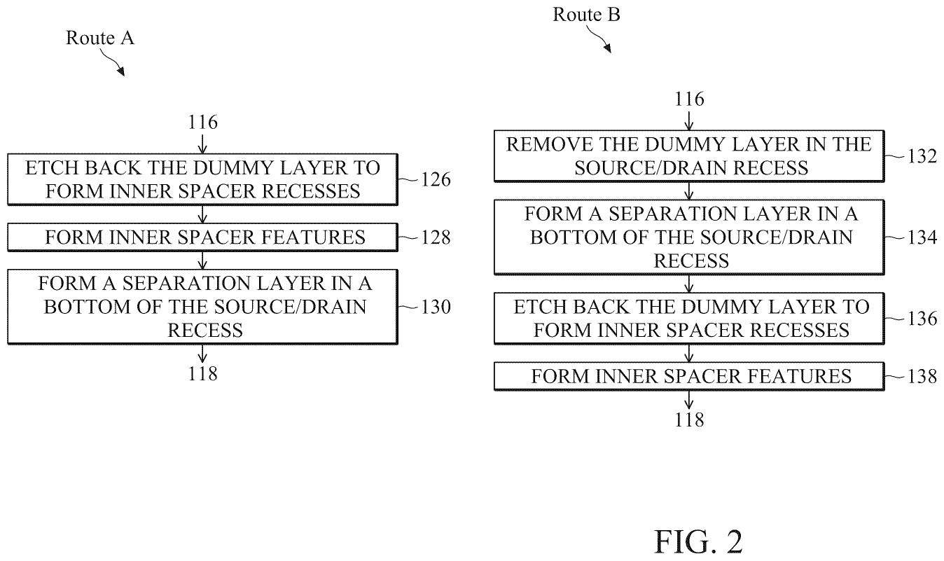

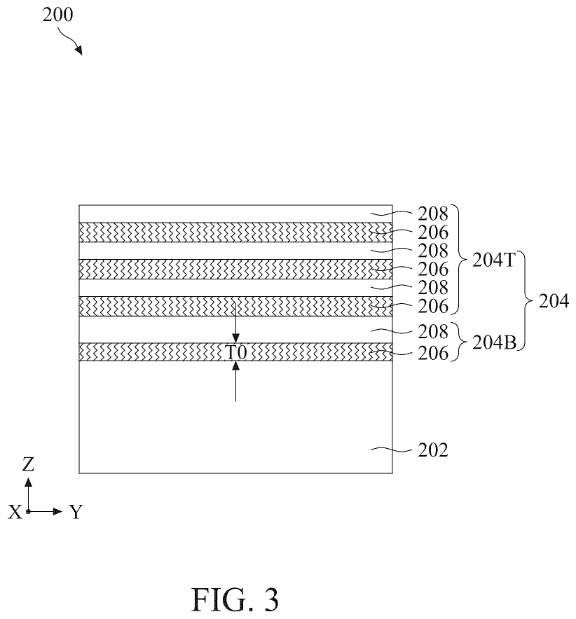

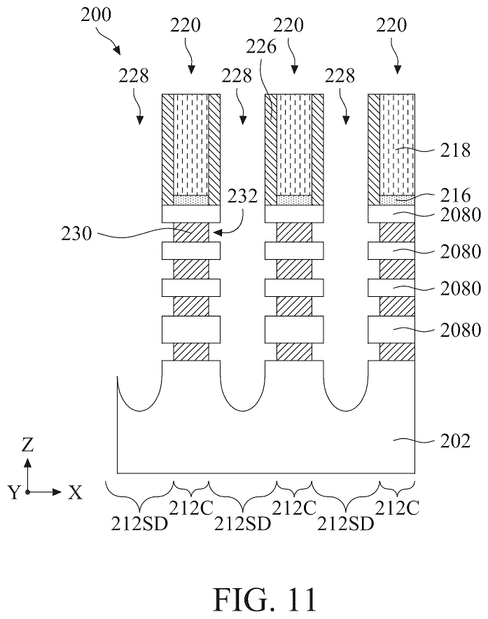

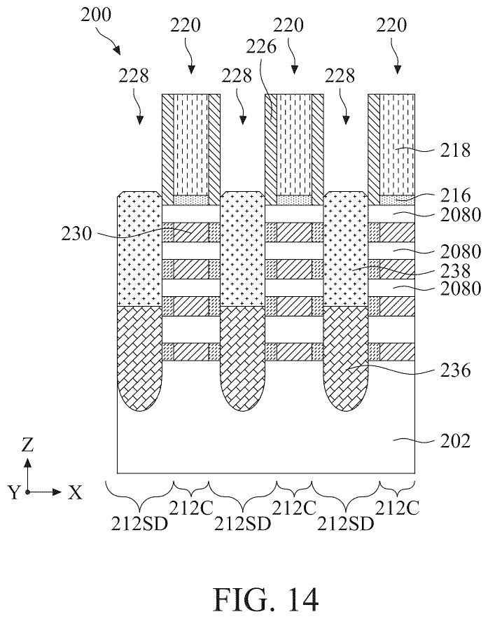

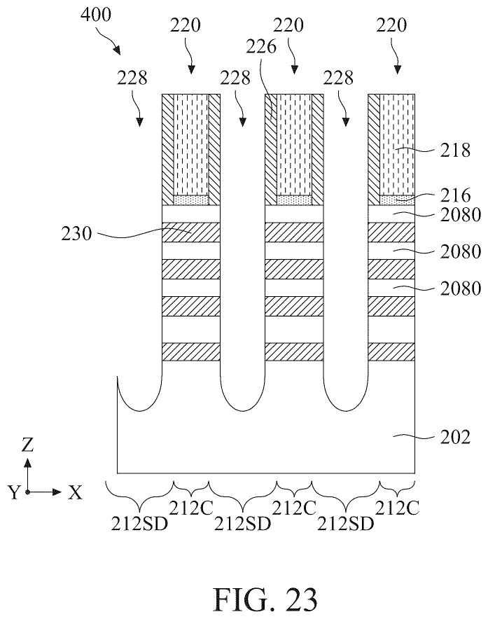

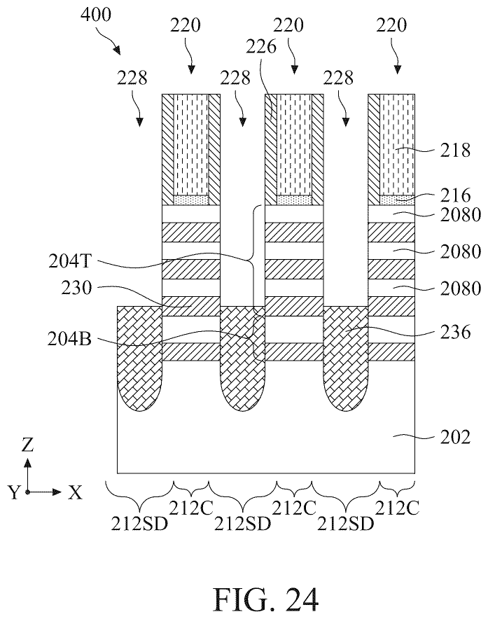

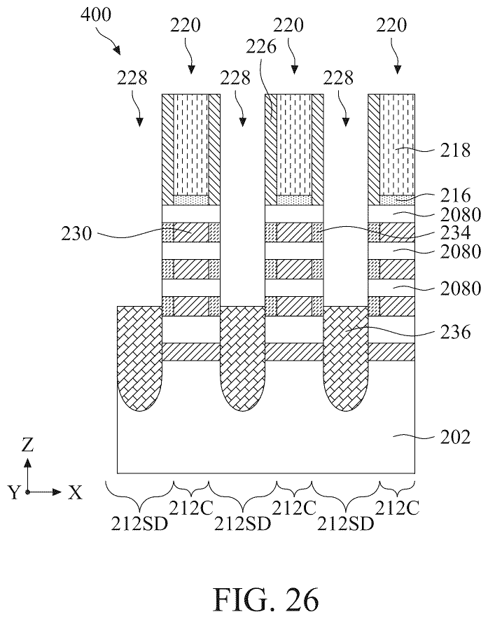

The various aspects of the present disclosure will now be described in more detail with reference to the figures. In that regard, FIG. 1 is a flowchart illustrating method 100 of forming a semiconductor structure according to embodiments of the present disclosure. FIG. 2 is a flowchart illustrating route A and route B, which are a portion of method 100 as in FIG. 1. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 3-28, which are fragmentary cross-sectional views of a structure 200 and alternative structures 300, 400, and 500 at different stages of fabrication according to embodiments of method 100 in FIGS. 1 and 2. Because the structures 200, 300, 400, and 500 will be fabricated into semiconductor structures or semiconductor devices, the structures 200, 300, 400, and 500 may be referred to herein as semiconductor structures 200, 300, 400, and 500 or semiconductor devices 200, 300, 400, and 500 as the context requires. For avoidance of doubts, the X, Y and Z directions in FIGS. 3-28 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Further, the semiconductor structures disclosed herein may include various other devices and features, such as other types of devices including additional transistors, bipolar junction transistors, resistors, capacitors, inductors, diodes, fuses, SRAM and/or other logic circuits, etc., but are simplified for a better understanding of the inventive concepts of the present disclosure. In some embodiments, the exemplary devices include a plurality of semiconductor devices (e.g., transistors), including n-type GAA transistors, p-type GAA transistors, PFETs, NFETs, etc., which may be interconnected.

Referring to FIGS. 1 and 3, method 100 includes a block 102 where a structure 200 is provided. As shown in FIG. 3, the structure 200 includes a substrate 202 and a stack 204 of alternating semiconductor layers formed over the substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that four (4) layers of the sacrificial layers 206 and four (4) layers of the channel layers 208 are alternately arranged as illustrated in FIG. 3, which is for illustrative purposes only and not intended to be limiting beyond what is specifically recited in the claims. It can be appreciated that any number of epitaxial layers may be formed in the stack 204. The number of layers depends on the desired number of channel members and the desired number of isolation structures (to be described below) for the semiconductor device 200. In some embodiments, the number of channel layers 208 is between 2 and 10. In some embodiments, the stack 204 includes a top stack 204T and a bottom stack 204B below the top stack 204T. The top stack 204T and the bottom stack 204B each include at least one channel layer 208. In some embodiments, the top stack 204T includes one to four channel layers. In some embodiments, the bottom stack 204B includes one to three channel layers. The sacrificial layer(s) 206 in the bottom stack 204B may each have a thickness TO of about 6 nm to about 60 nm.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

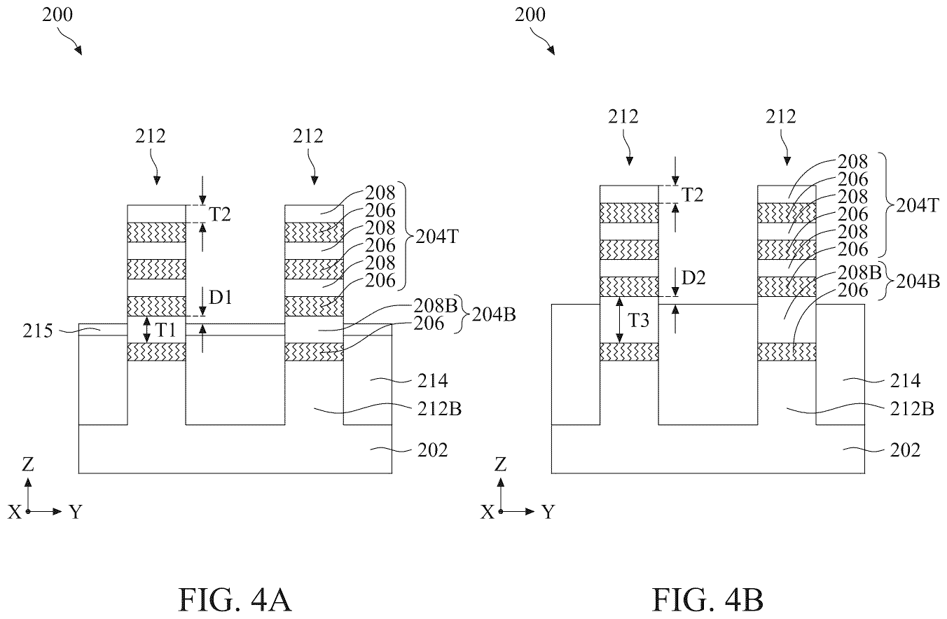

Referring to FIGS. 1 and 4A-4B, method 100 includes a block 104 where a fin-shaped structure 212 (also referred to as an active region 212 or a fin-like structure 212) is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIGS. 4A-4B, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIGS. 4A-4B, the fin-shaped structure 212 that includes the sacrificial layers 206 and the channel layers 208 extends vertically along the Z direction and lengthwise along the X direction. As shown in FIGS. 4A-4B, the fin-shaped structure 212 includes a base fin structure 212B patterned from the substrate 202. The patterned stack 204, including the sacrificial layers 206 and the channel layers 208, is disposed directly over the base fin structure 212B.

Still referring to FIGS. 1 and 4A-4B, method 100 includes a block 106 where an isolation feature 214 is formed adjacent to the fin-shaped structure 212. In some embodiments represented in FIG. 4A, the isolation feature 214 is disposed on sidewalls of the base fin structure 212B and a portion of the bottom stack 204B. In some embodiments, the isolation feature 214 may be formed in the trenches to isolate the fin-shaped structures 212 from a neighboring fin-shaped structure 212. In the disclosed embodiments, the isolation feature 214 may cover sidewalls of the sacrificial layer 206 in the bottom stack 204B. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 4A. The top stack 204T of the fin-shaped structure 212 rises above the STI feature 214 after the recessing, while the base fin structure 212B and the bottom stack 204B are embedded or buried in the isolation feature 214.

As depicted in FIG. 4A, a protection layer 215 is formed over the isolation feature 214. The protection layer 215 may be a single layer or multi-layers. In some embodiments, the protection layer 215 includes silicon nitride (SIN), silicon oxycarbonitride (SiCON), silicon oxide, silicon carbonitride (SiCN), silicon oxynitride (SiON), silicon oxycarbide (SiCO), a high-k dielectric material, or a combination thereof. A high-k dielectric material includes materials such as hafnium oxide, titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO). In some embodiments, the protection layer 215 includes silicon nitride, silicon oxycarbonitride, aluminum oxide, or a combination thereof.

The protection layer 215 may be deposited on a top surface of the isolation feature 214 using a combination of processes. The protection layer material may be first deposited over the structure 200 using a physical vapor deposition (e.g., sputtering) or chemical vapor deposition. Because the top facing surfaces are more in the line of sight, the deposited protection layer material is thicker on the top facing surfaces and thinner along the sidewalls of the fin-shaped structures 212. A bottom antireflective coating (BARC) layer (not depicted) may be deposited over the protection layer material using CVD, spin-on processes, or other suitable processes. The BARC layer may include silicon oxynitride (SiON), silicon oxycarbide, a polymer, or other suitable materials. The BARC layer may then be etched back to expose a top portion of the protection layer material. The protection layer material not covered by the BARC layer is then trimmed (e.g., by a dry etch process) using an oxygen-containing gas, a fluorine-containing gas, a chlorine-containing gas, a bromine-containing gas, an iodine-containing gas, other suitable gases and/or plasmas, and/or combinations thereof. The BARC layer is then removed using an ashing process or a dry etch process. Then, the protection layer material over sidewalls of the fin-shaped structure 212 is removed using an isotropic process, such as a wet etch process. As described above, because the protection layer material along the sidewalls of the fin-shaped structures 212 are thinner than the counterpart over the isolation feature 214, the protection layer material along the sidewalls of the fin-shaped structures 212 may be completely removed while a portion of the protection layer material over the isolation feature 214 remains as the protection layer 215. In some implementations, a thickness of the protection layer 215 is between about 1 nm and about 10 nm.

In the depicted embodiments in FIG. 4A, a topmost channel layer 208 (also referred to as the border semiconductor layer 208B) in the bottom stack 204B has a thickness T1. A channel layer 208 in the top stack 204 may have a thickness T2. T1 may be equal to or greater than T2. In some embodiments, T1 may be about 4 nm to about 10 nm. A top surface of the border semiconductor layer 208B may be coplanar with or higher than a top surface of the protection layer 215. A bottom surface of the border semiconductor layer 208B may be lower than the top surface of the protection layer 215.

In some other embodiments as depicted in FIG. 4B, the isolation feature 214 is formed similarly to the embodiments as described in FIG. 4A, and differences from the embodiments as described in FIG. 4A are as follows. In FIG. 4B, the protection layer 215 is omitted. In such embodiments, the border semiconductor layer 208B may have a thickness T3 greater than T1. T3 may be about 5 nm to about 30 nm. The top surface of the border semiconductor layer 208B may be coplanar with or higher than a top surface of the isolation feature 214. The bottom surface of the border semiconductor layer 208B may be lower than the top surface of the isolation feature 214.

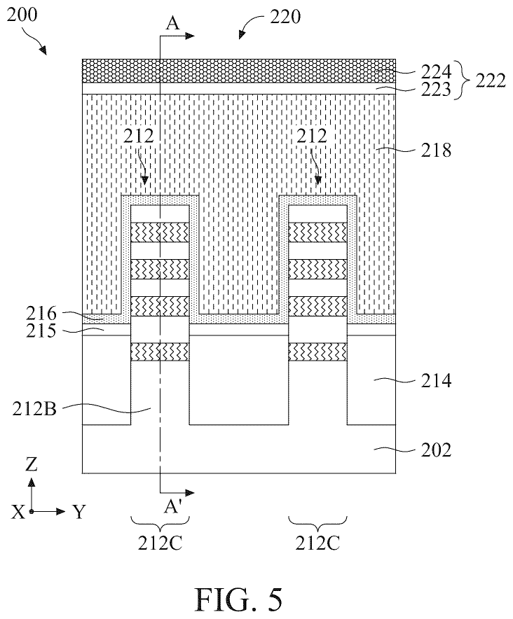

The following processes of method 100 may continue from embodiments with respect to FIG. 4A or FIG. 4B. In some of the following figures (e.g., FIGS. 5, 21D, and 22D), it is understood that the protection layer 215 may be omitted as in FIG. 4B.

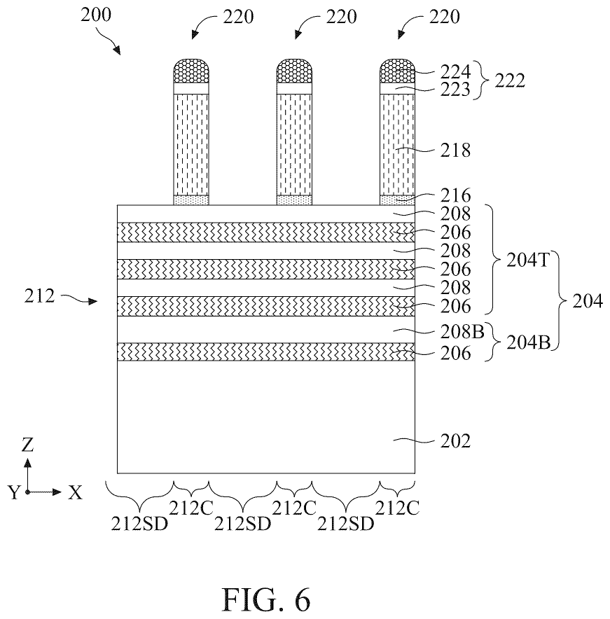

Referring to FIGS. 1, 5, and 6, method 100 includes a block 108 where a dummy gate stack 220 is formed over a channel region 212C of the fin-shaped structure 212. FIG. 6 illustrates a fragmentary cross-section view of the structure 200 taken along line A-A′ as in FIG. 5. In some embodiments, a gate replacement process (or gate-last process) is adopted where the dummy gate stack 220 (shown in FIGS. 5 and 6) serves as a placeholder to undergo various processes and is to be removed and replaced by a functional gate structure. Other processes and configuration are possible. In some embodiments illustrated in FIG. 6, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 6, the channel region 212C is disposed between two source/drain regions 212SD along the X direction.

The formation of the dummy gate stack 220 may include deposition of layers in the dummy gate stack 220 and patterning of these layers. Referring to FIG. 5, a dummy dielectric layer 216, a dummy electrode layer 218, and a gate-top hard mask layer 222 may be blanketly deposited over the structure 200. In some embodiments, the dummy dielectric layer 216 may be formed on the fin-shaped structure 212 using a chemical vapor deposition (CVD) process, an atomic layer deposition (ALD) process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 6. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 6, the dummy gate stack 220 is patterned such that it is only disposed over the channel region 212C, not disposed over the source/drain region 212SD.

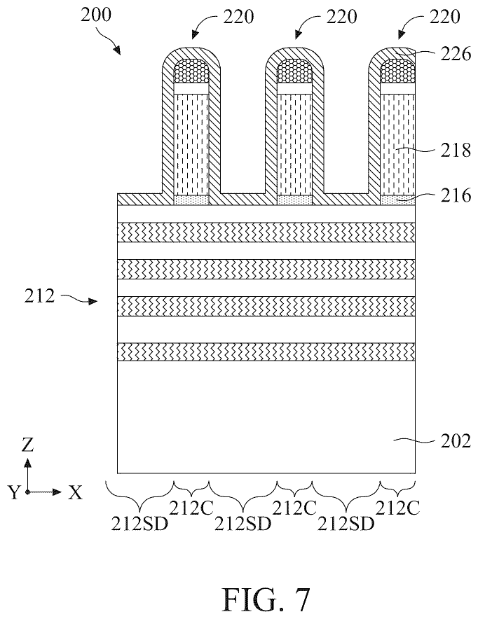

Referring to FIGS. 1 and 7, method 100 includes a block 110 where a gate spacer layer 226 is deposited over the structure 200, including over the dummy gate stack 220. In some embodiments, the gate spacer layer 226 is deposited conformally over the structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

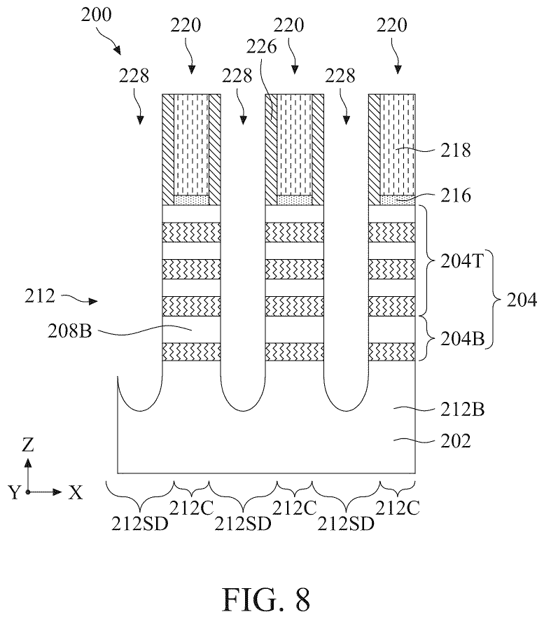

Referring to FIGS. 1 and 8, method 100 includes a block 112 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The anisotropic etch may include multiple etching processes. The resulting source/drain trench 228 extends vertically through the depth of the stack 204 and may partially extend into the substrate 202. An example dry etch process for block 112 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 8, the source/drain regions 212SD of the fin-shaped structure 212 are recessed to expose sidewalls of the sacrificial layers 206 and the channel layers 208 in both the top stack 204T and the bottom stack 204B. Because the source/drain trenches 228 extend below the stack 204 into the substrate 202 and/or the base fin structure 212B, the source/drain trenches 228 include bottom surfaces and lower sidewalls defined in the substrate 202 and/or the base fin structure 212B.

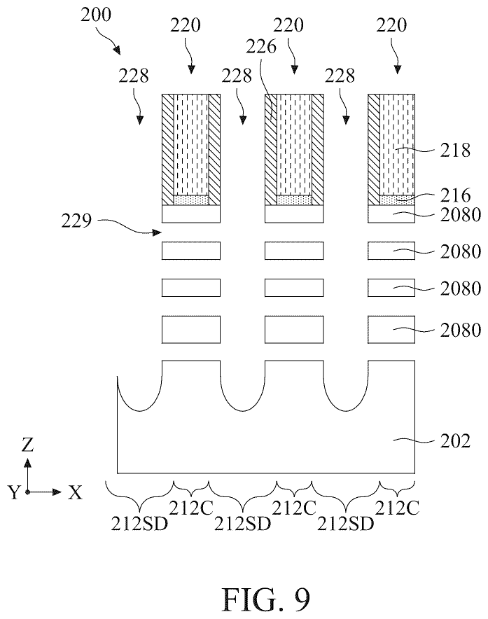

Referring to FIGS. 1 and 9, method 100 includes a block 114 where the plurality of channel layers 208 in the channel regions are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 8) to form channel members 2080 shown in FIG. 9. The channel members 2080 in the bottom stack 204B may also be referred to as semiconductor members 2080. The selective removal of the sacrificial layers 206 forms spaces 229 between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Depending on the design, the channel members 2080 may take form of nanowires, nanosheets, or other nanostructures.

While not explicitly shown, operations in block 114 may include a cleaning process to clean surfaces of the structure 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal.

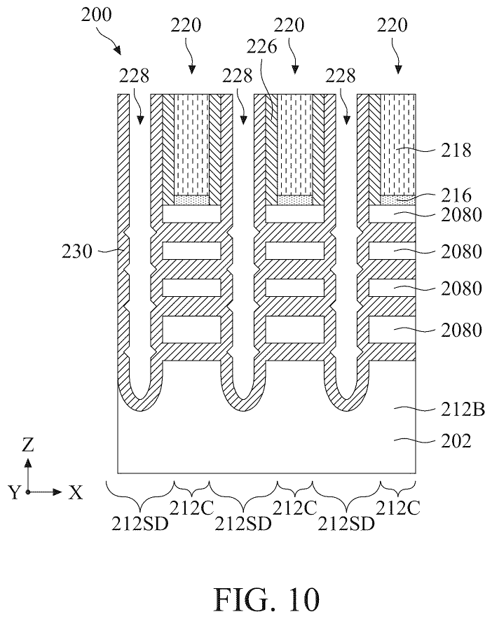

Referring to FIGS. 1 and 10, method 100 includes a block 116 where a dummy layer 230 is deposited around the channel members 2080 and over the source/drain trenches 228. The dummy layer 230 may include a dielectric material. The dielectric material may include an oxide, a nitride, a carbide, or a combination thereof. Examples of the dielectric material may include silicon oxide, SiCO, SIN, SiCN, and aluminum oxide (e.g., Al₂O₃). In some embodiments, the dummy layer 230 includes silicon oxide and/or aluminum oxide. The dummy layer 230 may be deposited using plasma enhanced chemical vapor deposition (PECVD) or ALD. As shown in FIG. 10, the dummy layer 230 fills the space 229 among the channel members 2080 and covers end sidewalls of the channel members 2080. Additionally, the dummy layer 230 is in direct contact with a sidewall of the gate spacer layer 226 and a top surface of the substrate 202 or the base fin structure 212B.

Referring to FIGS. 1, 2, and 11, in some embodiments, method 100 includes route A proceeding from block 116. Route A includes a block 126 where the dummy layer 230 is selectively and partially recessed to form inner spacer recesses 232 while the gate spacer layer 226, the dummy gate stack 220, the exposed portion of the substrate 202 or the base fin structure 212B, and the channel members 2080 are substantially unetched. The remaining dummy layer 230 may include a plurality of sublayers 230 interleaving with the channel members 2080. In an embodiment where the channel members 2080 consist essentially of silicon (Si) and the dummy layer 230 is formed of silicon oxide, the selective recess of the dummy layer 230 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

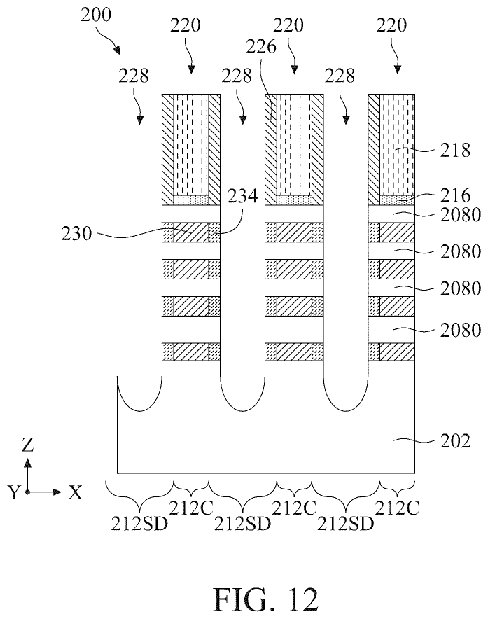

Referring to FIGS. 1, 2, and 12, route A includes a block 128 where inner spacer features 234 are formed in the inner spacer recesses 232. While not shown explicitly, operation at block 128 may include deposition of inner spacer material over the structure 200, and etching back the inner spacer material to form the inner spacer features 234 in the inner spacer recesses 232 (shown in FIG. 12). After the inner spacer recesses 232 are formed, an inner spacer material is deposited over the structure 200, including over the inner spacer recesses 232. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 232 as well as over the sidewalls of the channel members 2080 exposed in the source/drain trenches 228. Referring to FIG. 12, the deposited inner spacer material is then etched back to remove the inner spacer material from the sidewalls of the channel members 2080 to form the inner spacer features 234 in the inner spacer recesses 232.

Referring to FIGS. 1, 2, and 13, route A includes a block 130 where a separation layer 236 is formed in a bottom of the source/drain recess 228. While not explicitly shown, operations in block 130 may include a cleaning process to clean surfaces of the structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

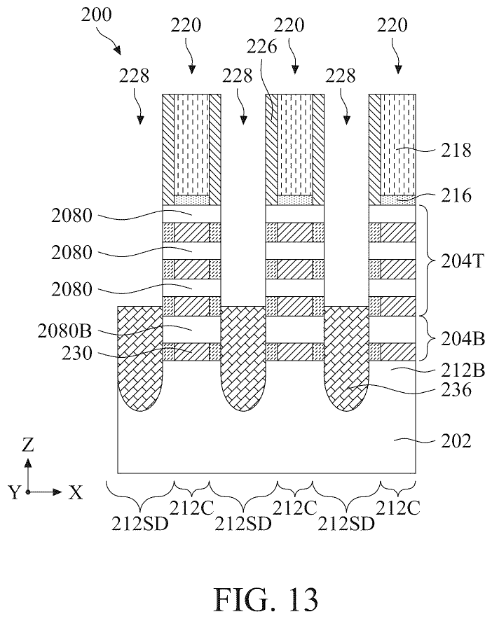

Referring to FIG. 13, the separation layer 236 may include a dielectric material, an epitaxial material, or a combination thereof. In the illustrated embodiment, a top surface of the separation layer 236 is higher than the bottom surface of the border semiconductor member 2080B (or a topmost surface of the dummy layer 230 below the border semiconductor member 2080B). In some embodiments, the top surface of the separation layer 236 is higher than or coplanar with a top surface of the border semiconductor member 2080B and lower than or coplanar with a bottom surface of a bottommost channel member 2080 of the top stack 204T. In some embodiments, the separation layer 236 is in direct contact with the inner spacer feature 234 between the border semiconductor member 2080B and the bottommost channel member 2080 of the top stack 204T. In the depicted embodiment, the top surface of the separation layer 236 has a flat profile. Alternatively, the top surface of the separation layer 236 may have a concave profile or a convex profile.

The dielectric material of the separation layer 236 may include any suitable dielectric material. In some embodiments, composition of the dielectric material is different from those of the channel members 2080, the dummy layer 230, the dummy electrode layer 218, the gate spacers 226, and the inner spacer features 234 to allow selective removal by an etching process. In some embodiments, the dielectric material may include silicon nitride (SIN), silicon oxynitride (SiON), silicon oxycarbonitride (SiOCN), silicon oxycarbide (SiOC), silicon carbonitride (SiCN), aluminum oxide, hafnium oxide, or other suitable materials. The dielectric material may be deposited over the structure 200 and etched back to form the separation layer 236 in the bottom of the source/drain trench 228.

In some embodiments, the epitaxial material of the separation layer 236 includes an undoped semiconductor material, such as undoped silicon (Si), undoped germanium (Ge), or undoped silicon germanium (SiGe). As used herein, the undoped semiconductor material is regarded as undoped when it is not intentionally doped. In an example process, the epitaxial material is epitaxially deposited over the structure 200 using molecular beam epitaxy (MBE), vapor-phase epitaxy (VPE), ultra-high vacuum CVD (UHV-CVD), or and/or other suitable epitaxial growth processes. Due to the crystalline orientation, the epitaxial material deposited on the exposed top surface of the substrate 202 or the base fin structure 212B possess less defect. This allows the epitaxial material to be selectively removed from surfaces other than the exposed top surface of the substrate 202 or the base fin structure 212B.

In some alternative embodiments, the epitaxial material of the separation layer 236 includes a counter dopant to reduce leakage into the bulk substrate 202. For example, the epitaxial material over which an n-type source/drain feature (to be described below) will be formed may include a p-type dopant, such as boron (B). For another example, the epitaxial material over which a p-type source/drain feature will be formed may include an n-type dopant, such as phosphorus (P), arsenic (As), or antimony (Sb).

Referring to FIGS. 1, 2, and 14, method 100 includes a block 118 proceeding from route A or route B. At block 118, a source/drain feature 238 is formed over the separation layer 236. Source/drain feature(s) 238 may refer to a source or a drain, individually or collectively dependent upon the context. The source/drain feature 238 each may be epitaxially and selectively formed from exposed sidewalls of the channel members 2080 in the top stack 204T and/or the epitaxial material (if any) of the separation layer 236 by using an epitaxial process, such as vapor phase epitaxy (VPE), ultrahigh vacuum chemical vapor deposition (UHV-CVD), molecular-beam epitaxy (MBE), and/or other suitable processes. The source/drain features 238 may include n-type source/drain features and/or p-type source/drain features dependent upon types of transistors. Exemplary n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. In some embodiments, the source/drain feature 238 includes more than one epitaxial semiconductor layer, where the epitaxial semiconductor layers may include the same or different materials and/or the same or different dopant concentrations.

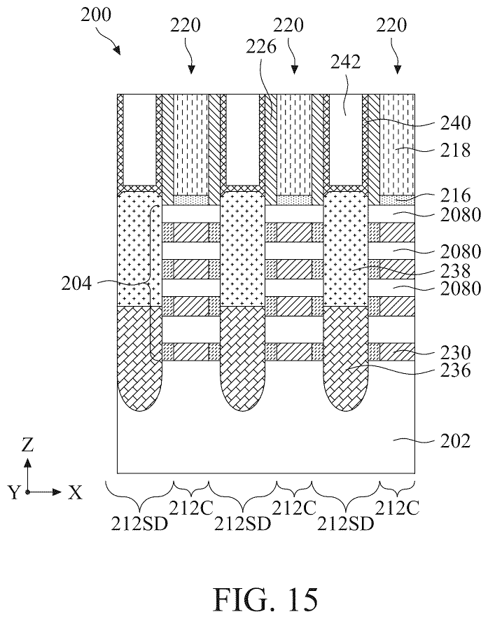

Referring to FIGS. 1 and 15, method 100 includes a block 120 where a contact etch stop layer (CESL) 240 and an interlayer dielectric (ILD) layer 242 are formed over the source/drain features 238. In some embodiments, the CESL 240 is deposited over the structure 200, including over the source/drain feature 238. The CESL 240 may include silicon nitride or aluminum nitride. In some implementations, the CESL 240 may be deposited using CVD or ALD. The ILD layer 242 is then deposited over the CESL 240. In some embodiments, the ILD layer 242 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 242 may be deposited using CVD, FCVD, spin-on coating, or a suitable deposition technique. Operations in block 120 may further include a planarization process, such as a chemical mechanical planarization (CMP) process.

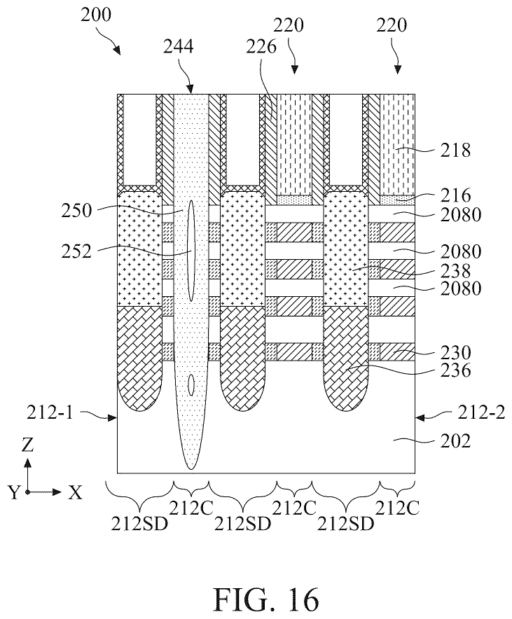

Referring to FIGS. 1 and 16, method 100 includes a block 122 where a dielectric feature 244 is formed to cut the fin-shaped structure 212 into two segments (e.g., segments 212-1 and 212-2). The dielectric feature 244 is oriented lengthwise in the Y-direction and provides isolation between the segments (e.g., segments 212-1 and 212-2). In the depicted embodiment, the dielectric feature 244 is disposed between two adjacent source/drain features 238. The dielectric feature 244 may include one or more dielectric materials 250. The one or more dielectric materials 250 may include silicon oxide, silicon nitride, silicon oxynitride, silicon oxycarbonitride, silicon carbonitride, silicon carbide, or a combination thereof. The dielectric feature 244 may include a single layer or multiple layers. In some embodiments, the dielectric feature includes one or more air gap 252.

The dielectric feature 244 may be formed by any suitable method. In some embodiments, operations in block 122 includes forming a trench to cut the fin-shaped structure 212 and filling the trench with the one or more dielectric materials 250. In some embodiments, the dielectric feature 244 is formed in a continuous-poly-on-diffusion-edge (CPODE) process. In a CPODE process, a polysilicon gate is replaced by a dielectric feature. For purposes of this disclosure, a “diffusion edge” may be equivalently referred to as an active edge, where for example an active edge abuts adjacent active regions. Before the CPODE process, the active edge may include a dummy GAA structure having a dummy gate structure (e.g., the dummy gate stack 220 on the left side in FIG. 15) and a plurality of vertically stacked nanostructures as channel layers (e.g., the stack 204 on the left side in FIG. 15). The subsequent CPODE etching process removes the dummy gate structure and the channel layers under the dummy gate structure to form a CPODE trench. One or more dielectric materials are then filled in the CPODE trench to form the dielectric feature. In such embodiments, the dielectric feature 244 is also referred to as a CPODE feature.

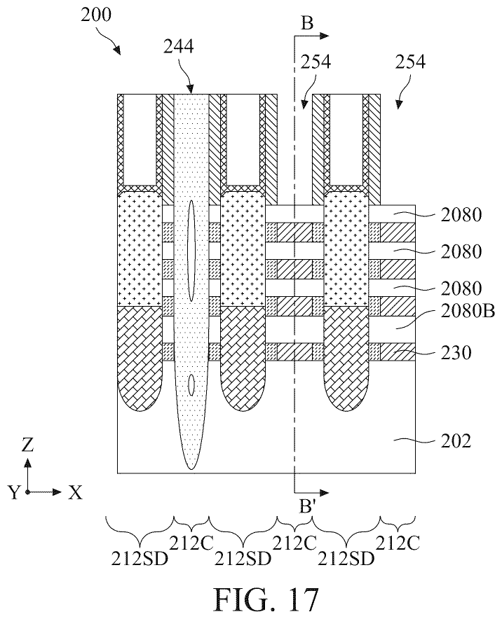

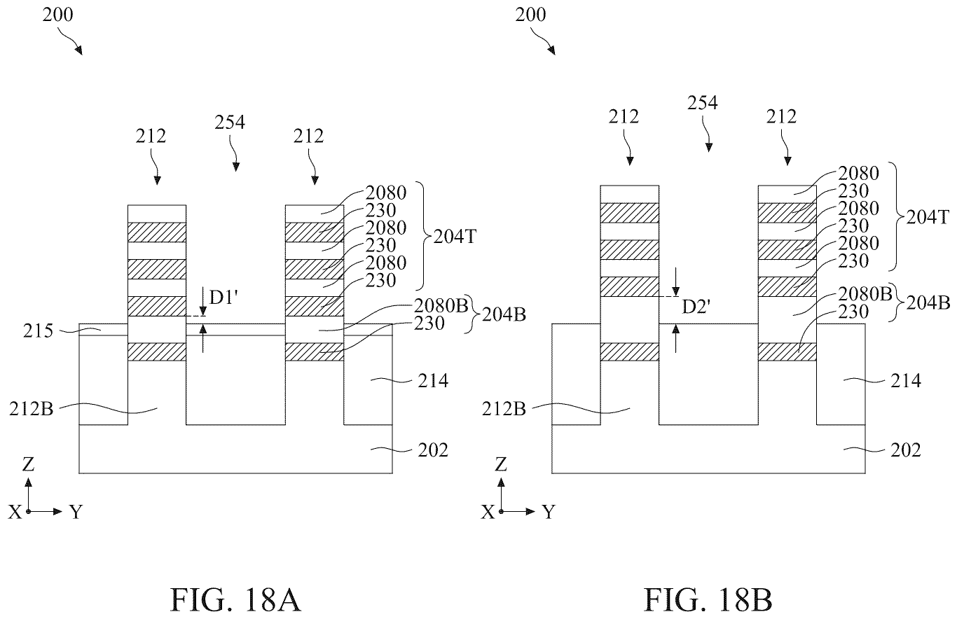

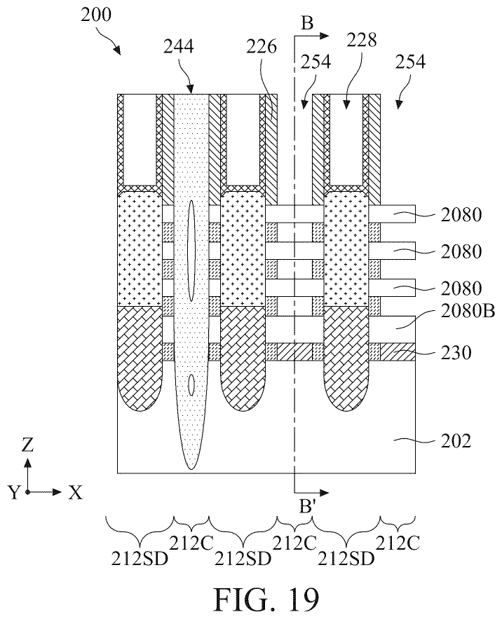

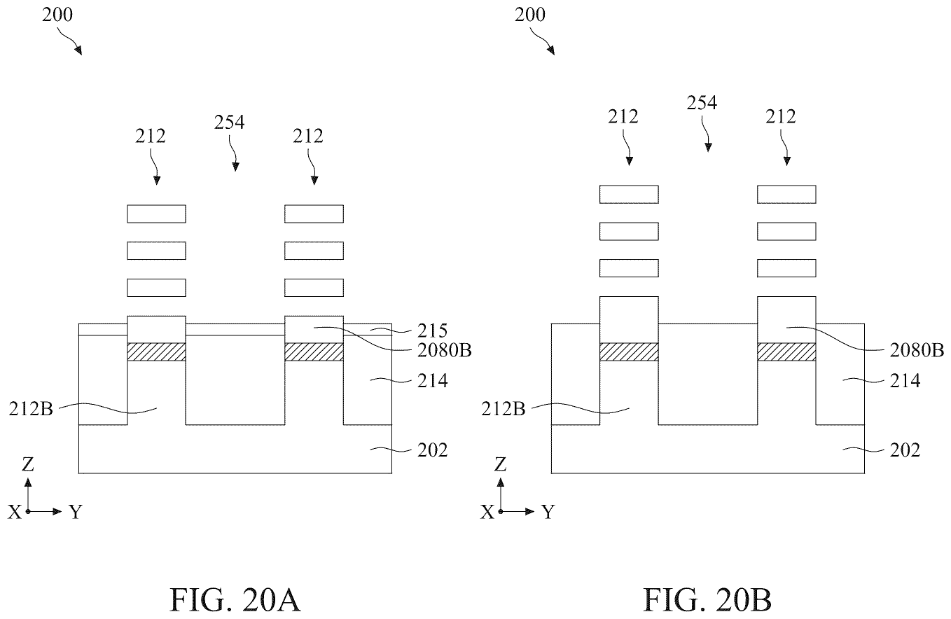

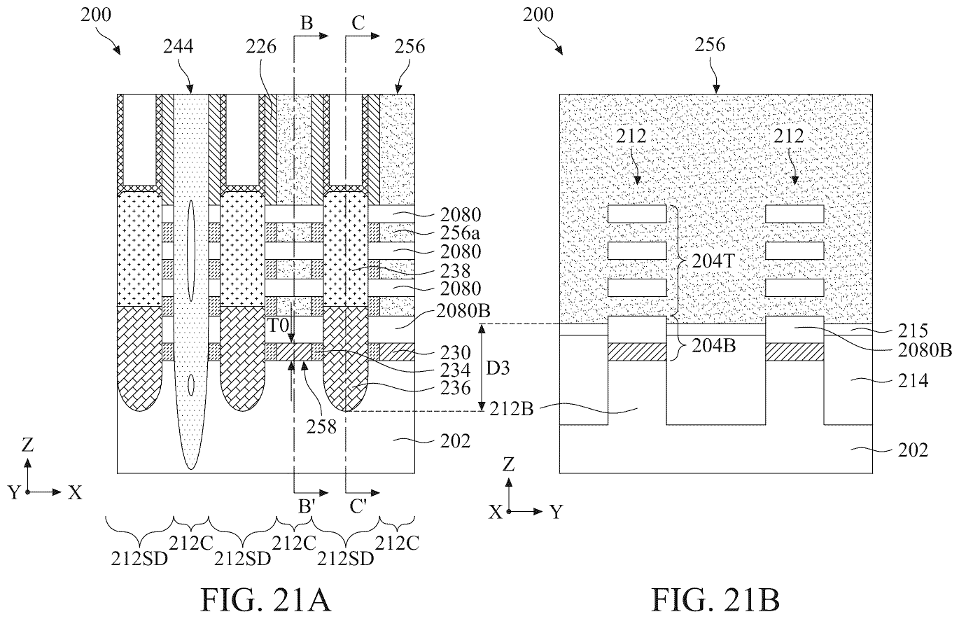

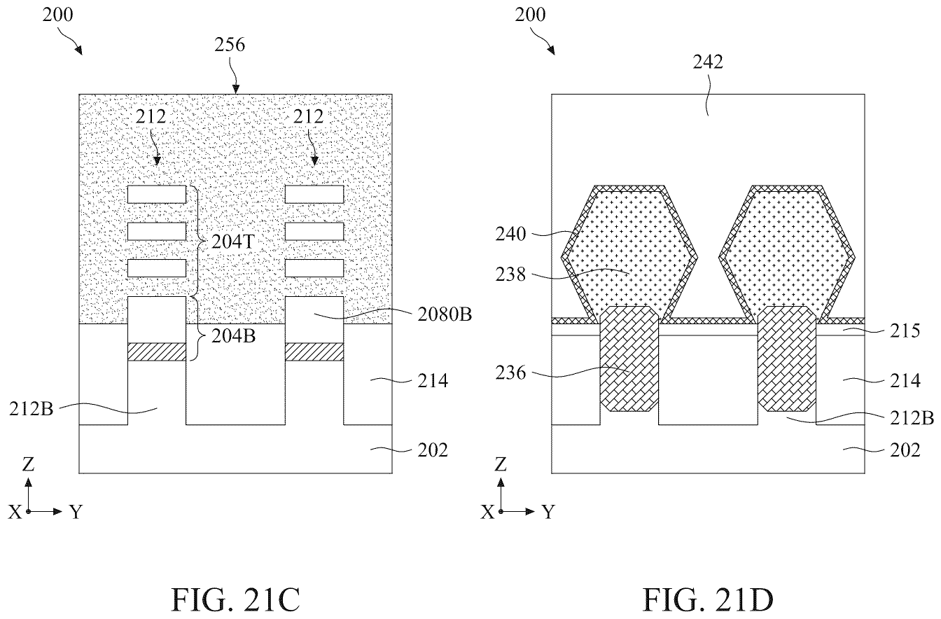

Referring to FIGS. 1 and 17-21D, method 100 includes a block 124 where the dummy gate stack 220 and the dummy layer 230 in the top stack 204T are replaced with a gate structure. Operations at block 124 may include removal of the dummy gate stack 220 (shown in FIGS. 17-18B), removal of the dummy layer 230 in the top stack 204T (shown in FIGS. 19-20B), and deposition of the gate structure 256 to wrap around each of the channel members 2080 in the top stack 204T (shown in FIGS. 21A-21D).

Referring to FIG. 17, the dummy gate stack 220 is removed. Before removing the dummy gate stack 220, the structure 200 may be planarized by a planarization process to expose the dummy gate stack 220. For example, the planarization process may include a CMP process. Exposure of the dummy gate stack 220 allows the removal of the dummy gate stack 220. The removal of the dummy gate stack 220 may include one or more etching processes that are selective to the material of the dummy gate stack 220. For example, the removal of the dummy gate stack 220 may be performed using a selective wet etch, a selective dry etch, or a combination thereof that is selective to the dummy gate stack 220.

FIGS. 18A and 18B illustrate fragmentary cross-sectional views of the structure 200 taken along line B-B′ as in FIG. 17 and correspond to structures presented in FIGS. 4A and 4B, respectively. In the depicted embodiment in FIG. 18A, after the removal of the dummy gate stack 220, a top surface of the protection layer 215 is exposed. The protection layer 215 may have a first etching rate and at least a portion of the protection layer 215 remains unetched during the etching processes of the removal of the dummy gate stack 220. In some embodiments, a vertical distance (e.g., along the Z-direction) between a top surface of the border semiconductor member 2080B (or the border semiconductor layer 208B) and the top surface of the protection layer 215 in FIGS. 4A and 18A is D1 and D1′, respectively. D1 may be greater than or equal to D1′. D1′ may be about 1 nm to about 5 nm, alternatively be about 1 nm to about 3 nm. The top surface of the protection layer 215 is coplanar with or higher than the bottom surface of the border semiconductor member 2080B. In the depicted embodiment in FIG. 18B, after the removal of the dummy gate stack 220, a top surface of the isolation feature 214 is exposed. The isolation feature 214 may have a second etching rate during the etching processes of the removal of the dummy gate stack 220. The second etching rate may be greater than the first etching rate. Thus, the removal of the dummy gate stack 220 may remove a portion of the isolation feature 214. In some embodiments, a vertical distance between a top surface of the border semiconductor member 2080B (or the border semiconductor layer 208B) and the top surface of the isolation feature 214 in FIGS. 4B and 18B is D2 and D2′, respectively. D2′ may be greater than D2. D2′ may be about 5 nm to about 30 nm, alternatively D2′ may be about 5 nm to about 10 nm. The top surface of the isolation feature 214 is coplanar with or higher than the bottom surface of the border semiconductor member 2080B.

After the removal of the dummy gate stack 220, the dummy layer 230 in the top stack 204T in the channel region 212C is exposed, while the dummy layer 230 in the bottom stack 204B remains as in FIGS. 18A-18B. A separate etch process may be performed to selectively remove the dummy layer 230 in the top stack 204T. For example, a selective wet etch process or a selective dry etch process may be performed. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. The gate spacer layer 226, the separation layer 236, the inner spacer features 234, the isolation features 214, the protection layer 215, and the dummy layer 230 may include different compositions for etching selectivity. In the depicted embodiment, the dummy layer in the bottom stack 204B is protected by surrounding features (e.g., sandwiched between the isolation features 214 along the Y-direction and sandwiched between the separation layers 236 along the X-direction, and disposed below the border semiconductor member 2080B) from contacting etchants of the etch process. Thus, the dummy layer 230 in the bottom stack 204B remains unetched while the dummy layer 230 in the top stack 204T is selectively removed. After the selective removal of the dummy layer 230 in the top stack 204T, the channel members 2080 in the top stack 204T in the channel region 212C are once again exposed as shown in FIGS. 19-20B. FIGS. 20A and 20B illustrate fragmentary cross-sectional views of the structure 200 taken along line B-B′ as in FIG. 19 and correspond to structures presented in FIGS. 18A and 18B, respectively. The selective removal of the dummy layer 230 forms a gate trench 254 that includes spaces between adjacent channel members 2080.

Referring to FIGS. 21A-21D, a gate structure 256 is formed to wrap around each of released as channel members 2080 in the top stack 204T. FIGS. 21B and 21C illustrate fragmentary cross-sectional views of the structure 200 taken along line B-B′ as in FIG. 21A and correspond to structures presented in FIGS. 20A and 20B, respectively. FIG. 21D illustrates a fragmentary cross-sectional view of the structure 200 taken along line C-C′ as in FIG. 21A. After the release of the channel members 2080 in the top stack 204T, the gate structure 256 is formed to wrap around each of the channel members 2080 in the top stack 204T. While not explicitly shown, the gate structure 256 includes an interfacial layer interfacing the channel members 2080 in the top stack 204T and the border semiconductor member 2080B in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure.

Referring to FIG. 21A, the gate structure 256 includes inner portions 256a that interleaves with the channel members 2080 in the top stack 204T. In the illustrated embodiment, a top surface of the separation layer 236 is higher than or coplanar with a bottom surface of a bottommost inner portion 256a and lower than or coplanar with a top surface of the bottommost inner portion 256a. The separation layer 236 may provide isolation among the base fin structure 212B or the substrate 202, the source/drain feature 238, and the channel member(s) 2080 in the bottom stack 204B (e.g., the border semiconductor member 2080B). The sublayer(s) of the remaining dummy layer 230 below the border semiconductor member 2080B and the adjacent inner spacer features 234 may collectively form an isolation structure 258. The isolation structure 258 may provide isolation among the base fin structure 212B and the semiconductor member(s) 2080 in the bottom stack 204B (e.g., 2080B). The isolation structure 258 may have the thickness TO as described above.

Referring to FIGS. 21A and 21B, a vertical distance (e.g., along the Z-direction) D3 between the top surface of the protection layer 215 and a bottom surface of the separation layer 236 is in a range of about 10 nm to about 60 nm. The isolation structure 258 may be formed between levels of the top surface of the protection layer 215 and the bottom surface of the separation layer 236. If D3 is too small, space for the isolation structure 258 may be too small. If D3 is too large, it may increase too much of the height of the structure 200 and the costs associated therewith. Similarly, referring to FIGS. 21A and 21C, in the embodiments where there is no protection layer 215, a vertical distance between the top surface of the isolation feature 214 and the bottom surface of the separation layer 236 may be in the same range as D3.

The semiconductor device 200 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

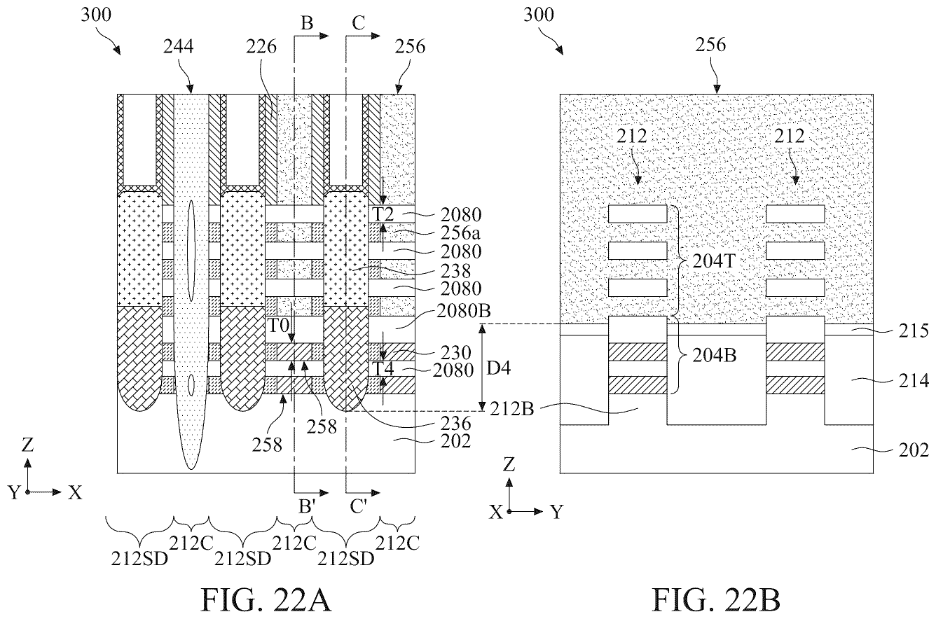

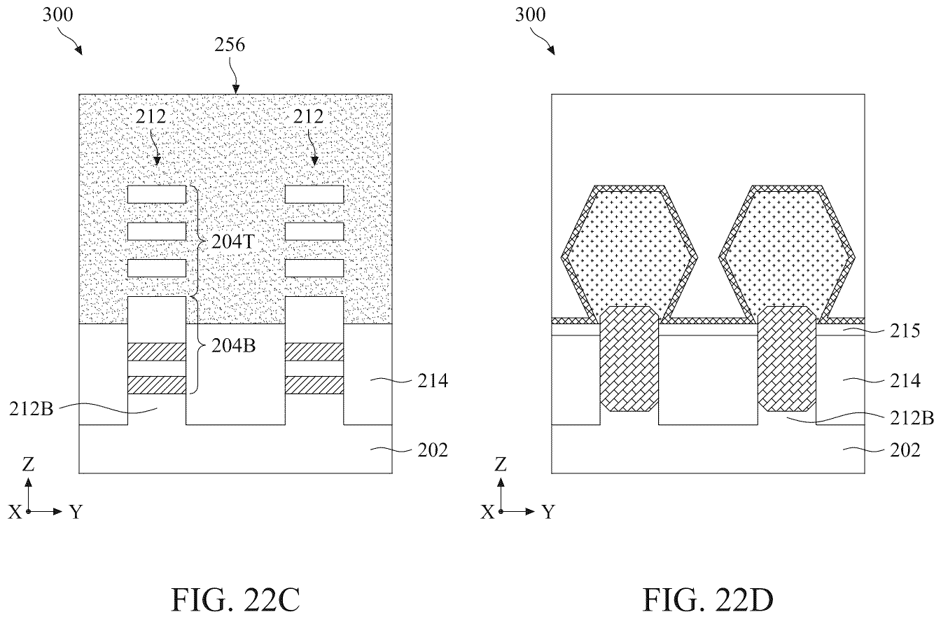

Referring to FIGS. 22A-22D, in some alternative embodiments, a structure 300 may be formed using method 100. Differences from the embodiments described above with respect to FIGS. 3-21D are described as follows. In the depicted embodiments in FIGS. 22A-22D, the bottom stack 204B includes more than one (e.g., two) channel members 2080 and more than one (e.g., two) isolation structures 258. Each of the isolation structures 258 may have the thickness TO as described above. The semiconductor member(s) 2080 below the border semiconductor member 2080B may have a thickness T4 similar to or greater than the thickness T2 of the channel members 2080 above the border semiconductor member 2080B. In such embodiments, a vertical distance D4 between the top surface of the protection layer 215 as in FIG. 22B (or the top surface of the isolation feature 214 as in FIG. 22C) and the bottom surface of the separation layer 236 may be greater than D3. D4 may be in a range of about 10 nm to about 70 nm. The number of the isolation structures 258 may be adjusted by adjusting D4. D4 may increase as the number and/or the thickness of the isolation structures 258 increase.

Referring to FIGS. 1, 2, and 23, in some alternative embodiments, method 100 includes route B proceeding from block 116. For the purpose of clarity, the structure in such embodiments is labeled as the structure 400. In some embodiments, route B includes a block 132 where the dummy layer 230 in the source/drain trench 228 is removed while the dummy layer 230 among the channel members 2080 (also referred to as sublayers of the dummy layer 230) remains as depicted. The removal of the dummy layer 230 from the source/drain trench 228 may use any suitable methods, such as those described in block 126. Process conditions (e.g., time duration, etchant) may be controlled in operations of block 132. Operations in block 132 may include an anisotropic etch. The dummy layer 230 among the channel members 2080 may be substantially unetched during operations in block 132.

Referring to FIGS. 1, 2, and 24, route B includes a block 134 where the separation layer 236 is formed in the bottom of the source/drain trench 228. Operations in block 134 may be similar to the operations in block 130 as described above. Differences from embodiments of block 130 are as follows. In some embodiments, the separation layer 236 is in direct contact with the sublayer of the dummy layer 230 between the bottommost channel member 2080 of the top stack 204T and the border semiconductor member 2080B. In the depicted embodiment, the separation layer 236 is on a sidewall of the dummy layer 230 in the bottom stack 204B. The dummy layer 230 in the bottom stack 204B extends between two adjacent isolation layers 236.

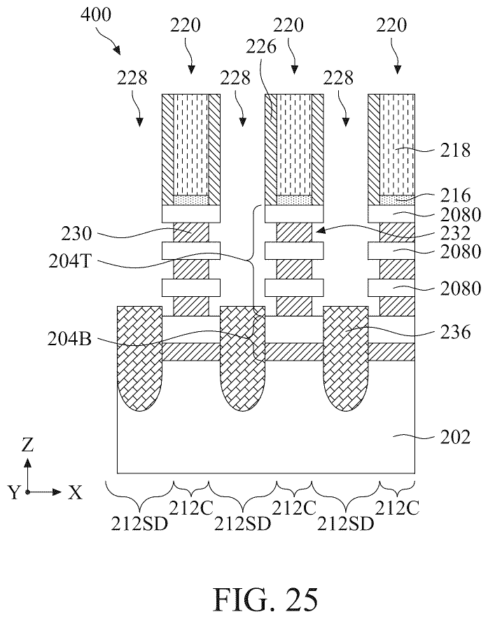

Referring to FIGS. 1, 2, and 25, route B includes a block 136 where the sublayers of the dummy layer 230 in the top stack 204T are selectively and partially recessed to form the inner spacer recesses 232 while the gate spacer layer 226, the dummy gate stack 220, the exposed channel members 2080, the separation layer 236, and the sublayer(s) of the dummy layer 230 in the bottom stack 204B are substantially unetched. Operations in block 136 may be similar to those described in block 126. A difference includes that the sublayer(s) of the dummy layer 230 in the bottom stack 204B are not recessed to form inner spacer recess(es). In some embodiments, the sublayer(s) of the dummy layer in the bottom stack 204B is protected by surrounding features (e.g., sandwiched between the isolation features 214 along the Y-direction, sandwiched between the separation layers 236 along the X-direction as depicted in FIG. 25, and disposed below the border semiconductor member 2080B) from contacting etchants of the selective etching process. Thus, the sublayer(s) of the dummy layer 230 in the bottom stack 204B remains unetched while the sublayers of the dummy layer 230 in the top stack 204T are selectively and partially recessed.

Referring to FIGS. 1, 2, and 26, route B includes a block 138 where the inner spacer features 234 are formed in the inner spacer recesses 232 similar to those described in block 128. A difference includes that no inner spacer feature(s) are formed between the sublayer(s) of the dummy layer 230 in the bottom stack 204B and the separation layer 236.

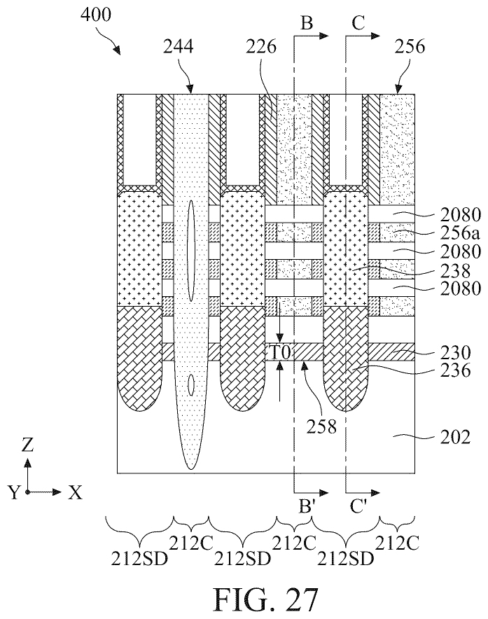

Referring to FIGS. 1, 2, and 27, the structure 400 may then proceed to undergo processes in blocks 118 to 124 as described above. FIG. 27 illustrates a fragmentary cross-sectional view of the structure 400 after operations in block 124. Differences from the structure 200 as in FIGS. 21A-21D are as follows. In the depicted embodiment of FIG. 27, the sublayer of the dummy layer 230 extends between the adjacent isolation layers 236. No inner spacer features are disposed between the dummy layer 230 and the adjacent isolation layers 236. In other words, the isolation structure 258 includes the dummy layer 230 but not inner spacer features. The isolation structure 258 may have the thickness TO as described above. Fragmentary cross-sectional views along lines B-B′ and C-C′ as in FIG. 27 are similar to FIGS. 21B-21D.

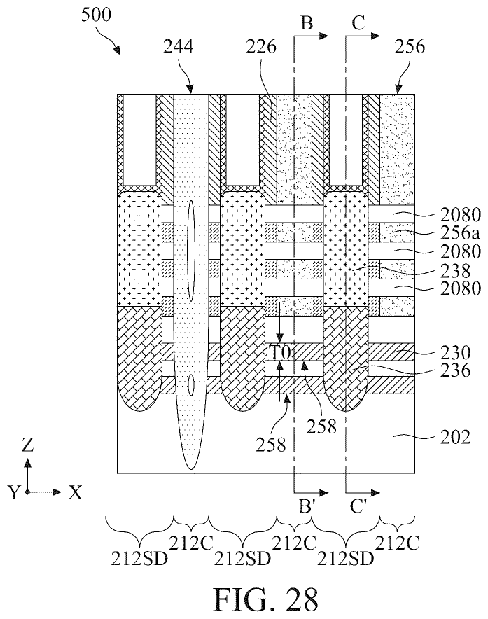

FIG. 28 illustrate a fragmentary cross-sectional view of an alternative structure 500 formed by method 100 after operations in block 124. The structure 500 may be formed similarly as the structure 400. Differences from the structure 300 as in FIGS. 22A-22D are as follows. In the depicted embodiment of FIG. 28, the sublayers of the dummy layer 230 extend between the adjacent isolation layers 236. No inner spacer features are disposed between the sublayers of the dummy layer 230 and the adjacent isolation layers 236. In other words, the isolation structures 258 each include a sublayer of the dummy layer 230 but not inner spacer features. Each of the isolation structures 258 may have the thickness TO as described above. Fragmentary cross-sectional views along lines B-B′ and C-C′ as in FIG. 28 are similar to FIGS. 22B-22D.

One of ordinary skill may recognize although FIGS. 3-28 illustrate GAA devices as embodiments, other examples of semiconductor devices (e.g., fork-sheet transistors, complementary field effect transistors (CFETs)) may benefit from aspects of the present disclosure.

Although not intended to be limiting, one or more embodiments of the present disclosure provide many benefits to a semiconductor device. For example, the present disclosure provides semiconductor structures having an isolation structure under the channel layers and extending between adjacent isolation layers below source/drain features. Thus, current leakage from the channel layers and from the source/drain features are mitigated, latch-up issues between the source/drain features may be prevented, trigger voltage fail may be avoided, and the overall performance of the semiconductor device may be improved.

In one exemplary aspect, the present disclosure is directed to a method. The method includes providing a fin base, forming a stack of alternating channel layers and sacrificial layers over the fin base, and forming an isolation feature disposed adjacent to the fin base. The fin base protrudes from a substrate. A top surface of the isolation feature is above a bottom surface of a bottommost channel layer. The method further includes forming a dummy gate structure over a channel region of the stack of alternating channel layers and sacrificial layers, depositing a gate spacer layer over the dummy gate structure, forming a source/drain recess in a source/drain region of the stack of alternating channel layers and sacrificial layers, selectively removing the sacrificial layers in the channel region to release the channel layers as channel members, depositing a dummy layer over the channel members and in the source/drain recess, selectively and partially recessing the dummy layer to form inner spacer recesses among the channel members, and forming inner spacer features in the inner spacer recesses. The remaining dummy layer includes sublayers interleaving with the channel members. The method further includes forming a separation layer over the source/drain region. A top surface of the separation layer is higher than a top surface of a bottommost sublayer. The method further includes forming a source/drain feature over the separation layer, removing the dummy gate structure and a top portion of the sublayers, and forming a gate structure to wrap around a top portion of the channel members.

In some embodiments, the separation layer includes a dielectric material, an undoped epitaxial layer, or a combination thereof, and the source/drain feature includes a doped epitaxial layer. In some embodiments, the method further includes forming a dielectric structure adjacent to the separation layer and the source/drain feature, and the dielectric structure extends through the channel layers and into the substrate. In some embodiments, the isolation feature includes a dielectric layer and a hard mask layer over the dielectric layer. In some embodiments, removing the dummy gate structure and the top portion of the sublayers further removes a top portion of the isolation feature below the dummy gate structure and forms a gate trench, and a top surface of a remaining portion of the isolation feature in the gate trench is above the bottom surface of the bottommost channel layer. In some embodiments, the method further includes removing the dummy layer in the source/drain recess before selectively and partially recessing the dummy layer to form the inner spacer recesses, forming the separation layer over the source/drain region is after removing the dummy layer in the source/drain recess and before selectively and partially recessing the dummy layer to form the inner spacer recesses. In some embodiments, the top portion of the sublayers includes at least one sublayer, and the top portion of the channel members includes at least one channel member. In some embodiments, after removing the dummy gate structure and the top portion of the sublayers, the bottommost sublayer remains. In some embodiments, in a cross-sectional view, the gate structure includes inner portions interleaving with the top portion of the channel members, the top surface of the separation layer is between levels of a top surface and a bottom surface of a bottommost inner portion of the gate structure.

In another exemplary aspect, the present disclosure is directed to a method. The method includes forming a stack of channel layers and sacrificial layers over a fin base. The sacrificial layers include a top portion and a bottom portion below the top portion. The method further includes forming an isolation feature disposed adjacent to the fin base and the stack, forming a dummy gate structure disposed over the stack and the isolation feature, forming a source/drain trench in the fin base and exposing sidewalls of the sacrificial layers, selectively removing the top portion of the sacrificial layers to form a top opening and the bottom portion of the sacrificial layers to form a bottom opening, depositing a dummy layer in the top opening and the bottom opening, selectively and partially recessing the dummy layer to form inner spacer recesses among the channel layers, forming inner spacer features in the inner spacer recesses, forming a source/drain feature in the source/drain trench, and replacing the dummy gate structure and the dummy layer in the top opening but not the dummy layer in the bottom opening with a metal gate structure.

In some embodiments, the bottom portion of the sacrificial layers includes at least one sacrificial layer, and a top surface of the isolation feature is above a topmost surface of the bottom portion of the sacrificial layers. In some embodiments, before forming the source/drain feature in the source/drain trench, the method further includes forming a separation layer in the source/drain trench. The separation layer includes a dielectric layer, an undoped epitaxial layer, or a combination thereof, and forming the source/drain feature includes forming the source/drain feature over the separation layer. In some embodiments, a top surface of the separation layer is above a topmost surface of the bottom portion of the sacrificial layers. In some embodiments, replacing the dummy gate structure and the dummy layer in the top opening but not the dummy layer in the bottom opening with the metal gate structure includes removing the dummy gate structure to form a gate trench, selectively removing the dummy layer in the top opening, while the dummy layer in the bottom opening is protected by the isolation feature and the source/drain feature, and forming the metal gate structure in the top opening and the gate trench. In some embodiments, the top portion of the sacrificial layers and the bottom portion of the sacrificial layers are separated by a border channel layer of the channel layers, the border channel layer has a first thickness, one channel layer of the channel layers and above the border channel layer has a second thickness smaller than the first thickness. In some embodiments, a top surface of the isolation feature is higher than a bottom surface of the source/drain trench by about 10 nm to about 60 nm.

In yet another exemplary aspect, the present disclosure is directed to a semiconductor structure. The semiconductor structure includes a fin base protruding from a substrate, two separation layers disposed over the substrate, two source/drain features disposed over the two separation layers, an isolation structure disposed over the fin base and connecting the two separation layers, and a stack of semiconductor layers disposed over the isolation structure. The stack of semiconductor layers includes a bottom semiconductor layer and top semiconductor layers disposed over the bottom semiconductor layer, the bottom semiconductor layer connects the two separation layers, and the top semiconductor layers connect the two source/drain features. The semiconductor structure further includes an isolation feature disposed adjacent to the fin base and the isolation structure and a metal gate structure wrapping around the top semiconductor layers. A top surface of the isolation feature is above a top surface of the isolation structure.

In some embodiments, the two separation layers include a dielectric material, an epitaxial material, or a combination thereof. In some embodiments, the top surface of the isolation feature is higher than a bottom surface of the two separation layers by about 10 nm to about 60 nm. In some embodiments, the isolation structure includes a dielectric layer and two inner spacer features sandwiching the dielectric layer, each of the two inner spacer features is disposed between the dielectric layer and one of the two separation layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a fin base, wherein the fin base protrudes from a substrate;
forming a stack of alternating channel layers and sacrificial layers over the fin base;
forming an isolation feature disposed adjacent to the fin base, wherein a top surface of the isolation feature is above a bottom surface of a bottommost channel layer;
forming a dummy gate structure over a channel region of the stack of alternating channel layers and sacrificial layers;
depositing a gate spacer layer over the dummy gate structure;
forming a source/drain recess in a source/drain region of the stack of alternating channel layers and sacrificial layers;
selectively removing the sacrificial layers in the channel region to release the channel layers as channel members;
depositing a dummy layer over the channel members and in the source/drain recess;
selectively and partially recessing the dummy layer to form inner spacer recesses among the channel members, wherein the remaining dummy layer includes sublayers interleaving with the channel members;
forming inner spacer features in the inner spacer recesses;
forming a separation layer over the source/drain region, wherein a top surface of the separation layer is higher than a top surface of a bottommost sublayer;
forming a source/drain feature over the separation layer;
removing the dummy gate structure and a top portion of the sublayers; and
forming a gate structure to wrap around a top portion of the channel members.

2. The method of claim 1, wherein the separation layer includes a dielectric material, an undoped epitaxial layer, or a combination thereof, and
the source/drain feature includes a doped epitaxial layer.

3. The method of claim 1, further comprising forming a dielectric structure adjacent to the separation layer and the source/drain feature,
wherein the dielectric structure extends through the channel layers and into the substrate.

4. The method of claim 1, wherein the isolation feature includes a dielectric layer and a hard mask layer over the dielectric layer.

5. The method of claim 1, wherein removing the dummy gate structure and the top portion of the sublayers further removes a top portion of the isolation feature below the dummy gate structure and forms a gate trench,
wherein a top surface of a remaining portion of the isolation feature in the gate trench is above the bottom surface of the bottommost channel layer.

6. The method of claim 1, further comprising removing the dummy layer in the source/drain recess before selectively and partially recessing the dummy layer to form the inner spacer recesses,
wherein forming the separation layer over the source/drain region is after removing the dummy layer in the source/drain recess and before selectively and partially recessing the dummy layer to form the inner spacer recesses.

7. The method of claim 1, wherein the top portion of the sublayers includes at least one sublayer, and
wherein the top portion of the channel members includes at least one channel member.

8. The method of claim 1, wherein after removing the dummy gate structure and the top portion of the sublayers, the bottommost sublayer remains.

9. The method of claim 1, wherein in a cross-sectional view, the gate structure includes inner portions interleaving with the top portion of the channel members,
wherein the top surface of the separation layer is between levels of a top surface and a bottom surface of a bottommost inner portion of the gate structure.

10. A method, comprising:
forming a stack of channel layers and sacrificial layers over a fin base, wherein the sacrificial layers include a top portion and a bottom portion below the top portion;
forming an isolation feature disposed adjacent to the fin base and the stack;
forming a dummy gate structure disposed over the stack and the isolation feature;
forming a source/drain trench in the fin base and exposing sidewalls of the sacrificial layers;
selectively removing the top portion of the sacrificial layers to form a top opening and the bottom portion of the sacrificial layers to form a bottom opening;
depositing a dummy layer in the top opening and the bottom opening;
selectively and partially recessing the dummy layer to form inner spacer recesses among the channel layers;
forming inner spacer features in the inner spacer recesses;
forming a source/drain feature in the source/drain trench; and
replacing the dummy gate structure and the dummy layer in the top opening but not the dummy layer in the bottom opening with a metal gate structure.

11. The method of claim 10, wherein the bottom portion of the sacrificial layers includes at least one sacrificial layer, and
wherein a top surface of the isolation feature is above a topmost surface of the bottom portion of the sacrificial layers.

12. The method of claim 10, wherein before forming the source/drain feature in the source/drain trench, the method further includes:
forming a separation layer in the source/drain trench, wherein the separation layer includes a dielectric layer, an undoped epitaxial layer, or a combination thereof, and
wherein forming the source/drain feature includes forming the source/drain feature over the separation layer.

13. The method of claim 12, wherein a top surface of the separation layer is above a topmost surface of the bottom portion of the sacrificial layers.

14. The method of claim 10, wherein replacing the dummy gate structure and the dummy layer in the top opening but not the dummy layer in the bottom opening with the metal gate structure includes:
removing the dummy gate structure to form a gate trench;
selectively removing the dummy layer in the top opening, while the dummy layer in the bottom opening is protected by the isolation feature and the source/drain feature; and
forming the metal gate structure in the top opening and the gate trench.

15. The method of claim 10, wherein the top portion of the sacrificial layers and the bottom portion of the sacrificial layers are separated by a border channel layer of the channel layers,
wherein the border channel layer has a first thickness,
wherein one channel layer of the channel layers and above the border channel layer has a second thickness smaller than the first thickness.

16. The method of claim 10, wherein a top surface of the isolation feature is higher than a bottom surface of the source/drain trench by about 10 nm to about 60 nm.

17. A semiconductor structure, comprising:
a fin base protruding from a substrate;
two separation layers disposed over the substrate;
two source/drain features disposed over the two separation layers;
an isolation structure disposed over the fin base and connecting the two separation layers;
a stack of semiconductor layers disposed over the isolation structure, wherein the stack of semiconductor layers includes a bottom semiconductor layer and top semiconductor layers disposed over the bottom semiconductor layer, wherein the bottom semiconductor layer connects the two separation layers, and wherein the top semiconductor layers connect the two source/drain features;
an isolation feature disposed adjacent to the fin base and the isolation structure, wherein a top surface of the isolation feature is above a top surface of the isolation structure; and
a metal gate structure wrapping around the top semiconductor layers.

18. The semiconductor structure of claim 17, wherein the two separation layers include a dielectric material, an epitaxial material, or a combination thereof.

19. The semiconductor structure of claim 17, wherein the top surface of the isolation feature is higher than a bottom surface of the two separation layers by about 10 nm to about 60 nm.

20. The semiconductor structure of claim 17, wherein the isolation structure includes a dielectric layer and two inner spacer features sandwiching the dielectric layer, wherein each of the two inner spacer features is disposed between the dielectric layer and one of the two separation layers.
